(19) United States
(12) Patent Application Publication
(10) Pub. No.: US 2026/0023903 A1
(43) Pub. Date: Jan. 22, 2026

(54) SYSTEM AND METHOD FOR AUTOMATED VERIFICATION OF BATTERY MANAGEMENT SYSTEM

(71) Applicant: Samsung SDI Co., Ltd., Yongin-si (KR)

(72) Inventor: Kihyun Kwon, Yongin-si (KR)

(73) Assignee: Samsung SDI Co., Ltd., Yongin-si (KR)

(21) Appl. No.: 19/267,137

(22) Filed: Jul. 11, 2025

(30) Foreign Application Priority Data
Jul. 22, 2024 (KR) 10-2024-0096724

(51) Int. Cl. G06F 30/30

(52) U.S. Cl. CPC G06F 30/30

(57) ABSTRACT

The present disclosure relates to a system and method for automated verification of a battery management system for a battery pack, an energy storage device, etc., and the problem to be solved is to enable automated verification for items that should be determined by modifying internal variable information or verifying results with the internal variable information during white box verification of the internal architecture logic of BMS firmware of an ESS. There is provided a system for automated verification of a BMS, including a device for automated verification configured to create a test case sequence for testing firmware operation items of the BMS, perform a simulation on the BMS, and model operation items of the BMS, a BMS controller that is connected to the device for automated verification and controls the BMS to operate by applying modeled data for the operation items to the BMS, and a BMS internal variable acquirer that acquires internal variable information of the BMS during execution of the simulation.

### CROSS-REFERENCE TO RELATED APPLICATIONS

This present application claims priority to and the benefit under 35 U.S.C. § 119(a)-(d) of Korean Patent Application No. 10-2024-0096724, filed on Jul. 22, 2024, the entire disclosure of which is incorporated herein by reference.

### FIELD

The present disclosure relates to a system and method for automated verification of a battery management system for a battery pack, an energy storage device, etc.

### BACKGROUND

Secondary batteries are batteries that can be charged and discharged, unlike primary batteries that cannot be recharged. Low-capacity secondary batteries are used in small portable electronic devices such as smartphones, feature phones, laptop computers, digital cameras, and camcorders, and large-capacity secondary batteries are widely used as power sources for driving motors and power storage batteries in hybrid vehicles, electric vehicles, and like. These secondary batteries include an electrode assembly that includes a positive electrode and negative electrode, a case that accommodates the electrode assembly, and an electrode terminal connected to the electrode assembly.

The above information disclosed in this Background section is for enhancement of understanding of the background of the present disclosure, and therefore, it may contain information that does not constitute a related (or prior) art.

### SUMMARY

The object of the present disclosure is to solve the above problem by enabling automated verification for items that should be determined by modifying internal variable information or verifying results with the internal variable information during verification using white box testing of the internal architecture logic of BMS firmware of an energy storage system (ESS).

To solve the problems described herein, according to an aspect of the present disclosure, there is provided a system for automated verification of a battery management system (BMS), including a device for automated verification configured to create a test case sequence for testing firmware operation items of the BMS, perform a simulation on the BMS, and model operation items of the BMS, a BMS controller that is connected to the device for automated verification and controls the BMS to operate by applying modeled data for the operation items to the BMS, and a BMS internal variable acquirer that acquires internal variable information of the BMS during execution of the simulation.

To solve the problems described herein, according to another aspect of the present disclosure, there is provided a device for automated verification of the BMS, the device being configured to create a test case sequence for testing a firmware operation item of the BMS, model an operation item of the BMS, perform a simulation on the BMS, transmit modeled data for the operation item to a BMS controller to control operation of the BMS, and receive internal variable information of the BMS and reflect the internal variable information in the test case sequence during execution of the simulation.

To solve the problems described herein, according to still another aspect of the present disclosure, there is provided a method for automated verification of a BMS, including performing a simulation on the BMS using a test case sequence created to test a firmware operation item of the BMS and data obtained by modeling an operation item of the BMS, and acquiring internal variable information of the BMS during execution of the simulation.

Aspects and features of the present disclosure are not limited to those described herein, and other aspects and features not specifically mentioned herein will be clearly understood by those skilled in the art from the description of the present disclosure herein.

### BRIEF DESCRIPTION OF THE DRAWINGS

The following drawings attached to the present specification illustrate embodiments of the present disclosure and further describe aspects and features of the present disclosure together with the detailed description of the present disclosure. Thus, the present disclosure should not be construed as being limited to the drawings, in which:

FIG. 1 is a diagram schematically illustrating a pouch-type secondary battery;

FIG. 2 is a cross-sectional view of a cylindrical secondary battery;

FIG. 3A is a top perspective view illustrating an appearance of a prismatic secondary battery;

FIG. 3B is a cross-sectional view taken along line I-I′ of FIG. 3A;

FIG. 4 is an exemplary diagram of a secondary battery module in which secondary batteries are arranged;

FIG. 5 is an exemplary diagram of a secondary battery pack configured to apply the secondary battery module illustrated in FIG. 4 to an actual product;

FIG. 6 is a diagram for describing a vehicle including the secondary battery pack illustrated in FIG. 5;

FIG. 7 is a schematic configuration diagram of a system for automated verification of a battery management system (BMS) based on hardware in the loop simulator (HILs);

FIG. 8A is a configuration diagram of a system for automated verification according to some embodiments of the present disclosure;

FIG. 8B is a configuration diagram of a system for automated verification according to some embodiments;

FIG. 9 illustrates an embodiment showing that an integrated development environment (IDE) may be used as a BMS internal variable acquirer of FIGS. 8A and 8B;

FIG. 10A is a flowchart for describing embodiments of an operation process in which a BMS internal variable acquirer acquires an internal variable of BMS firmware during execution of automated verification by the device for automated verification;

FIG. 10B is a flowchart illustrating a process of embodiments in which the operation process of FIG. 10A is further detailed; and

FIG. 11 is a diagram for describing an example of automated verification of BMS firmware using a method for automated verification according to the present disclosure.

### DETAILED DESCRIPTION

Hereinafter, embodiments of the present disclosure will be described, in detail, with reference to the accompanying drawings. The terms or words used in the present specification and claims are not to be narrowly interpreted according to their general or dictionary meanings and should be interpreted as having meanings and concepts that are consistent with the technical idea of the present disclosure on the basis of the principle that an inventor can be his/her own lexicographer to appropriately define concepts of terms to describe his/her disclosure in the best way.

The embodiments described in this specification and the configurations shown in the drawings are only some embodiments of the present disclosure and do not represent all of the aspects, features, and embodiments of the present disclosure. Accordingly, it should be understood that there may be various equivalents and modifications that can replace or modify one or more embodiments or features therein described herein at the time of filing this application.

It will be understood that if an element or layer is referred to as being “on,” “connected to,” or “coupled to” another element or layer, it may be directly on, connected, or coupled to the other element or layer or one or more intervening elements or layers may also be present. When an element or layer is referred to as being “directly on,” “directly connected to,” or “directly coupled to” another element or layer, there are no intervening elements or layers present. For example, if a first element is described as being “coupled” or “connected” to a second element, the first element may be directly coupled or connected to the second element or the first element may be indirectly coupled or connected to the second element via one or more intervening elements.

In the figures, dimensions of the various elements, layers, etc. may be exaggerated for clarity of illustration. The same reference numerals designate the same elements. As used herein, the term “and/or” includes any and all combinations of one or more of the associated listed items. Further, the use of “may” if describing embodiments of the present disclosure relates to “one or more embodiments of the present disclosure.” Expressions, such as “at least one of” and “any one of,” if preceding a list of elements, modify the entire list of elements and do not modify the individual elements of the list. When phrases such as “at least one of A, B and C, “at least one of A, B or C,” “at least one selected from a group of A, B and C,” or “at least one selected from among A, B and C” are used to designate a list of elements A, B and C, the phrase may refer to any and all suitable combinations or a subset of A, B and C, such as A, B, C, A and B, A and C, B and C, or A and B and C. As used herein, the terms “use,” “using,” and “used” may be considered synonymous with the terms “utilize,” “utilizing,” and “utilized,” respectively. As used herein, the terms “substantially,” “about,” and similar terms are used as terms of approximation and not as terms of degree, and are intended to account for the inherent variations in measured or calculated values that would be recognized by those of ordinary skill in the art.

It will be understood that, although the terms first, second, third, etc. may be used herein to describe various elements, components, regions, layers, and/or sections, these elements, components, regions, layers, and/or sections should not be limited by these terms. These terms are used to distinguish one element, component, region, layer, or section from another element, component, region, layer, or section. Thus, a first element, component, region, layer, or section discussed herein could be termed a second element, component, region, layer, or section without departing from the teachings of example embodiments.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

The terminology used herein is for the purpose of describing embodiments of the present disclosure and is not intended to be limiting of the present disclosure. As used herein, the singular forms “a” and “an” are intended to include the plural forms as well, unless the context clearly indicates otherwise. It will be further understood that the terms “includes,” “including,” “comprises,” and/or “comprising,” if used in this specification, specify the presence of stated features, integers, steps, operations, elements, and/or components but do not preclude the presence or addition of one or more other features, integers, steps, operations, elements, components, and/or groups thereof.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112 (a) and 35 U.S.C. § 132 (a).

References to two compared elements, features, etc. as being “the same” may mean that they are “substantially the same.” Thus, the phrase “substantially the same” may include a case having a deviation that is considered low in the art, for example, a deviation of 5% or less. In addition, if a certain parameter is referred to as being uniform in a given region, it may mean that it is uniform in terms of an average. Throughout the specification, unless otherwise stated, each element may be singular or plural.

Arranging an arbitrary element “above (or below)” or “on (under)” another element may mean that the arbitrary element may contact the upper (or lower) surface of the element, and another element may also be interposed between the element and the arbitrary element located on (or under) the element.

In addition, it will be understood that if a component is referred to as being “linked,” “coupled,” or “connected” to another component, the elements may be directly “coupled,” “linked” or “connected” to each other, or another component may be “interposed” between the components.”

Throughout the specification, if “A and/or B” is stated, it means A, B or A and B, unless otherwise stated. That is, “and/or” includes any or all combinations of a plurality of items enumerated. When “C to D” is stated, it means C or more and D or less, unless otherwise specified.

The terminology used herein is for the purpose of describing embodiments of the present disclosure and is not intended to limit the present disclosure.

Verification of firmware, which is the internal software of a battery management system (BMS) of an energy storage system (ESS) product, may be done through automated verification by creating test cases for the requirements of specific functions using hardware in the loop simulator (HILs). However, in the case of black box testing, which does not require knowledge of the internal structure or design of firmware, automated verification is possible, but in the case of white box testing for verifying the internal logic of the firmware, automated verification is difficult.

That is, in cases where internal variable information of firmware cannot be checked through communication, when it is intended to verify the corresponding item thereof, there is a difficulty in that the corresponding item should be manually verified by inputting external input conditions and using a debugging tool (e.g., an embedded workbench (EW) of IAR).

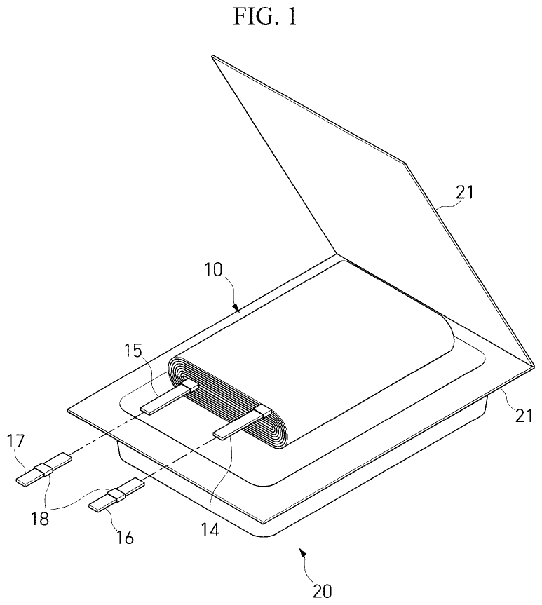

FIG. 1 schematically illustrates the pouch-type secondary battery.

The pouch-type secondary battery includes an electrode assembly 10 and a pouch 20 that accommodates the electrode assembly 10.

The electrode assembly 10 is the same as that illustrated in FIG. 1. The first electrode tab 14 and the second electrode tab 15 of the electrode assembly 10 may be electrically connected to respective external first and second terminal leads 16 and 17 by welding. Each of the first terminal lead 16 and the second terminal lead 17 may be attached with a tab film 18 for insulation from the pouch 20.

The pouch 20 may be sealed by having sealing parts 21 at the edges thereof come into contact with one another while accommodating the electrode assembly 10 therein, in which circumstance the sealing may be achieved with the tab film 18 interposed between the sealing parts 21. The sealing parts 21 of the pouch 20 may each be made of a thermal fusion material that generally has weak adhesion to metal. Thus, it may be fused to the pouch 20 by interposing the thin tab film 18 between the sealing parts 21.

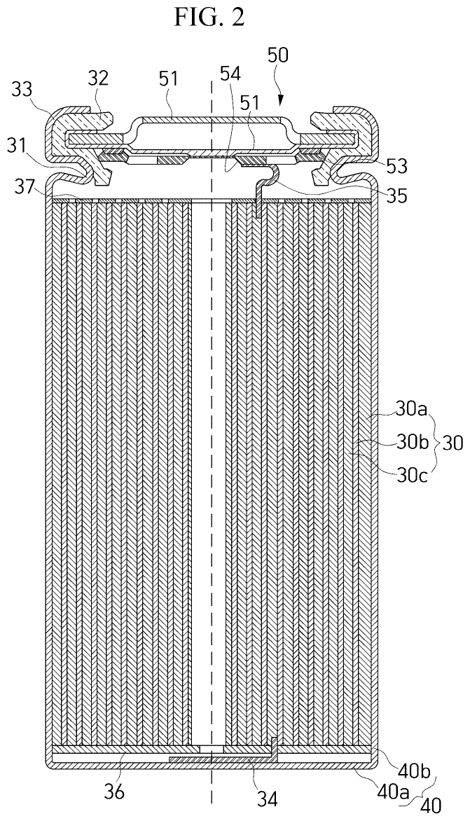

FIG. 2 illustrates a cylindrical secondary battery. As shown in FIG. 1, a secondary battery includes an electrode assembly 30, a case 40 accommodating the electrode assembly 30 and an electrolyte therein, a cap assembly 50 coupled to an opening of the case 40 to seal the case, and an insulating plate 37 positioned between the electrode assembly 30 and the cap assembly 50 inside the case 40.

The electrode assembly 30 may include a separator 30b and a first electrode 30c and a second electrode 30a positioned with the separator interposed therebetween and may be wound in a jelly-roll shape.

The first electrode 30c includes a first substrate and a first active material layer on the first substrate. A first lead tab 35 may extend outwardly from a first uncoated portion of the first substrate at where the first active material layer is not located, and the first lead tab 35 may be electrically connected to the cap assembly 50.

The second electrode 30a includes a second substrate and a second active material layer on the second substrate. A second lead tab 34 may extend outwardly from a second uncoated portion of the second substrate at where the second active material layer is not located, and the second lead tab 34 may be electrically connected to the case 40. The first lead tab 35 and the second lead tab 34 may extend in opposite directions.

The first electrode 30c may act as a positive electrode. In such embodiments, the first substrate may be made of, for example, an aluminum foil, and the first active material layer may include, for example, a transition metal oxide. The second electrode 30a may act as a negative electrode. In such embodiments, the second substrate may be made of, for example, a copper foil or a nickel foil, and the second active material layer may include graphite, for example.

The separator 30b prevents a short circuit between the first electrode 30c and the second electrode 30a while allowing movement of lithium ions therebetween. The separator 32b may be made of, for example, a polyethylene film, a polypropylene film, a polyethylene-polypropylene film, or the like.

The case 40 accommodates the electrode assembly 30 and, together with the cap assembly 50, forms the external appearance of the secondary battery. The case 40 may have a substantially cylindrical body portion 40b and a bottom portion 40a connected to one side (e.g., to one end) of the body portion 40b. A beading part 31 (e.g., a bead) deformed inwardly may be formed in the body portion 40b, and a crimping part 33 (e.g., a crimp) bent inwardly may be formed at an open end of the body portion 40b.

The beading part 31 can reduce or prevent movement of the electrode assembly 30 inside the case 40 and can facilitate seating of the gasket 32 and the cap assembly 50. The crimping part 33 may firmly fix the cap assembly 50 by pressing the edge of the case 40 against the gasket 32. The case 40 may be formed of iron plated with nickel, for example.

The cap assembly 50 may be fixed to the inside of the crimping part by a gasket 32 to seal the case 40. The cap assembly 50 may include a cap up 51, a safety vent 52, a cap down 53, an insulating member, and a sub plate 54 but is not limited thereto and may be modified in various ways.

The cap up 51 may be positioned at the uppermost part of the cap assembly 50. The cap up 51 may include a terminal part that protrudes upwardly and is connected to an external circuit, and an outlet for discharging gas may be arranged around the terminal part.

The safety vent 52 may be located under the cap up 51. The safety vent 52 may include a protrusion part that protrudes convexly downwardly and is connected to the sub plate 54, and at least one notch may be formed in the safety vent 52 around the protrusion part.

When gas is generated due to overcharging or abnormal operation of the secondary battery, the protrusion part is deformed upwardly by the pressure and separates from the sub plate 54 while the safety vent 52 is cut (e.g., bursts or tears) along the notch. The cut safety vent 52 may prevent the secondary battery from exploding by allowing for the gas to be discharged to the outside.

The cap down 53 may be below the safety vent 52. The cap down 53 may have a first opening for exposing the protrusion part of the safety vent 52 and a second opening for gas discharge. The insulating member may be positioned between the safety vent 52 and the cap down 53 to insulate the safety vent 52 and the cap down 53.

The sub plate 54 may be under the cap down 53. The sub plate 54 may be fixed to a lower surface of the cap down 53 to block the first opening of the cap down 53, and the protrusion part of the safety vent 52 may be fixed to the sub plate 54. The first lead tab 35, which is drawn out from the electrode assembly 30, may be fixed to the sub plate 54. Accordingly, the cap up 51, the safety vent 52, the cap down 53, and the sub plate 54 may be electrically connected to the first electrode 30c of the electrode assembly 30.

The insulating plate 37 may be positioned to be in contact with the electrode assembly 30 below the beading part 31. The insulating plate 37 may have a tab opening through which the first lead tab 35 is drawn out. The cap assembly 30, which is electrically connected to the first electrode 30c by the first lead tab 35, may face the electrode assembly 30 with an insulating plate 37 interposed therebetween and may maintain a state of being insulated (e.g., electrically insulated) from the electrode assembly 30 by the insulating plate 37.

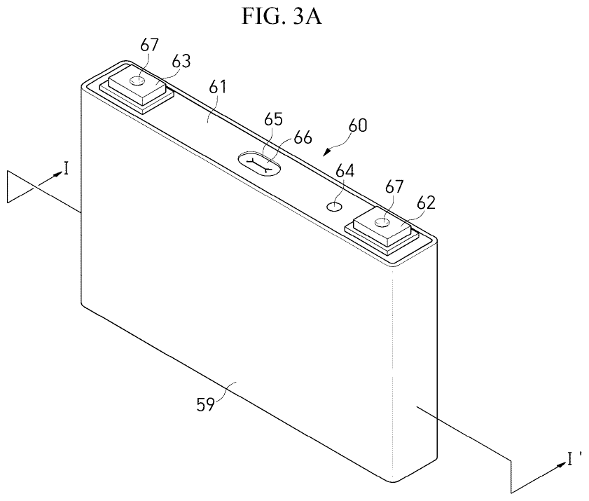

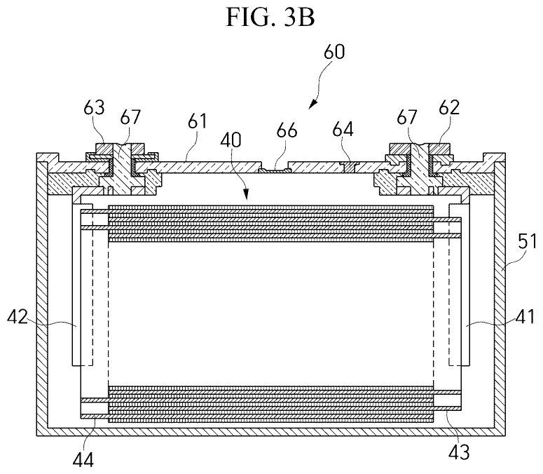

FIG. 3A is a top perspective view of a prismatic secondary battery.

A case 59 defines an overall appearance of the prismatic secondary battery, and may be made of a conductive metal, such as aluminum, aluminum alloy, or nickel-plated steel. In addition, the case 59 may provide a space for accommodating an electrode assembly therein.

A cap assembly 60 may include a cap plate 61 that covers the opening of the case 51. In some examples, the case 59 and the cap plate 61 may be made of a conductive material. Here, a first terminal 63 and a second terminal 62 may be electrically connected to respective positive and negative (or negative and positive) electrodes inside the case, and may be installed to protrude outwardly through the cap plate 61. The cap plate 61 may be equipped with an electrolyte injection port 64 formed to install a sealing plug (or seal pin), and a vent 66 formed with a notch 65. The vent 66 is for discharging gas generated inside the secondary battery.

FIG. 3B is a cross-sectional view taken along the line I-I′ of FIG. 3A, and illustrates according to some embodiments of the present disclosure. With reference to FIG. 2, the internal structure of the prismatic secondary battery and the coupling structure with the cap assembly 60 will be further described.

As shown in FIG. 3B, a prismatic secondary battery may include an electrode assembly 40, a first current collector 41, a first terminal 62, a second current collector 42, a second terminal 63, a case 51, and a cap assembly 60.

An electrode assembly 40 may be formed by winding or stacking a stack of a first electrode plate, a separator, and a second electrode plate, which are formed as thin plates or films. When the electrode assembly 40 is a wound stack, a winding axis may be arranged in parallel to the longitudinal direction (e.g., the y direction) of the case 51. In some embodiments, the electrode assembly 40 is a stack type rather than a winding type, and the shape of the electrode assembly 40 is not limited in the present disclosure. In addition, the electrode assembly 40 may be a Z-stack electrode assembly in which a positive electrode plate and a negative electrode plate are inserted into both sides of a separator, which is then bent into a Z-stack. In addition, one or more electrode assemblies may be stacked such that long sides of the electrode assemblies are adjacent to one another and accommodated in the case, and the number of electrode assemblies in the case is not limited in the present disclosure. The first electrode plate of the electrode assembly may act as a negative electrode, and the second electrode plate may act as a positive electrode. Of course, the reverse is also possible.

The first electrode plate may be formed by applying a first electrode active material, such as graphite, carbon, or the like, to a first electrode current collector formed of a metal foil, such as copper, a copper alloy, nickel, a nickel alloy, or the like. The first electrode plate may include a first electrode tab 43 (e.g., a first uncoated portion) that is a region to which the first electrode active material is not applied. The first electrode tab 43 may act as a current flow path between the first electrode plate and the first current collector 41. In some embodiments, when the first electrode plate is manufactured, the first electrode tab 43 is formed by being cut in advance to protrude to one side of the electrode assembly 40, or the first electrode tab 43 protrudes to one side of the electrode assembly 40 more than (e.g., farther than or beyond) the separator without being separately cut.

The second electrode plate may be formed by applying a second electrode active material, such as a transition metal oxide, on a second electrode current collector formed of a metal foil, such as aluminum or an aluminum alloy. The second electrode plate may include a second electrode tab 44 (e.g., a second uncoated portion) that is a region to which the second electrode active material is not applied. The second electrode tab 44 may act as a current flow path between the second electrode plate and the second current collector 42. In some embodiments, the second electrode tab 44 may be formed by being cut in advance to protrude to the other side (e.g., the opposite side) of the electrode assembly when the second electrode plate is manufactured, or the second electrode plate may protrude to the other side of the electrode assembly more than (e.g., farther than or beyond) the separator without being separately cut.

The separator prevents or substantially reduces instances of a short circuit between the first electrode and the second electrode while allowing movement of lithium ions therebetween. The separator may be made of, for example, a polyethylene film, a polypropylene film, a polyethylene-polypropylene film, or the like.

In some embodiments, the electrode assembly 40 is accommodated in the case 10 along with an electrolyte.

In the electrode assembly 40, the first current collector 41 and the second current collector 42 may be welded and connected to the first electrode tab 43 extending from the first electrode plate and the second electrode tab 44 extending from the second electrode plate, respectively. As mentioned herein, in some embodiments in which the first electrode tab 43 and the second electrode tab 44 are located at the top of the electrode assembly 40, the first and second current collectors are located at the top of the electrode assembly 40.

As illustrated in FIG. 3B, the first current collector 41 and the second current collector 42 are connected to the first terminal 62 and the second terminal 63 through connection members 67, respectively. In some embodiments, the connection members 67 may each have an outer peripheral surface that is threaded, and may be fastened to the first terminal 62 and the second terminal 63 by screwing. However, the present disclosure is not limited thereto. For example, the connection members 67 may also be coupled to the first terminal 62 and the second terminal 63 by riveting or welding.

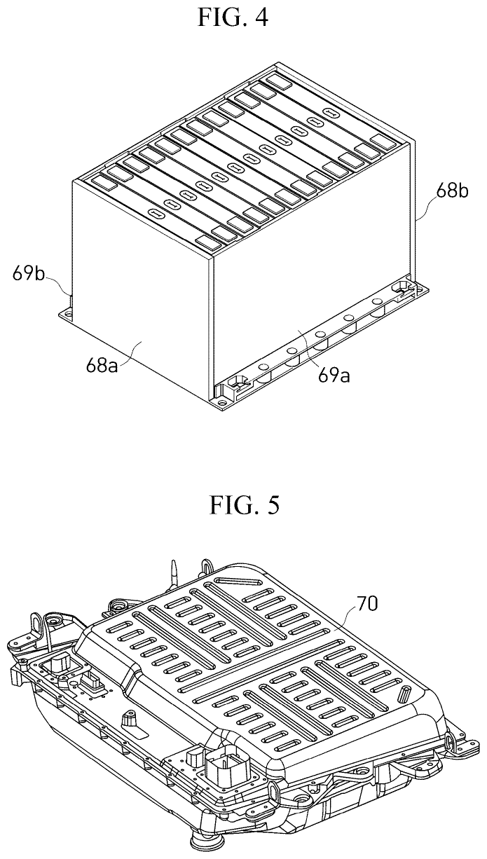

FIG. 4 is a perspective view of a secondary battery module in which secondary batteries are arranged according to embodiments of the present disclosure. With the increase in secondary battery capacity for driving electric vehicles or the like, a secondary battery module may be manufactured by arranging a plurality of secondary battery cells transversely and/or longitudinally and connecting them together. The plurality of secondary batteries may be arranged in a space defined by a pair of facing end plates 68a and 68b and a pair of facing side plates 69a and 69b. The secondary batteries may be arranged in an arrangement (direction) and number to obtain desired voltage and current specifications.

FIG. 5 is a perspective view of a battery pack 70 according to embodiments of the present disclosure. Referring to FIG. 5, the battery pack 70 may include an assembly to which individual batteries are electrically connected and a pack housing accommodating the same. In the drawings, for convenience of illustration, components including a bus bar, a cooling unit, external terminals for electrically connecting batteries, etc., are not shown.

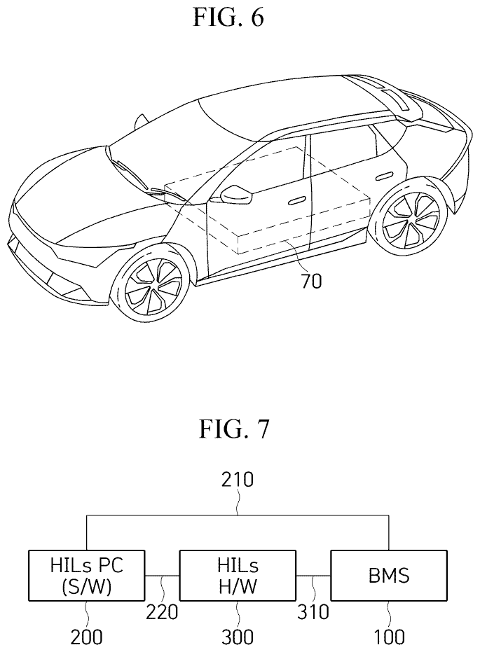

The battery pack 70 may be mounted on (or in) a vehicle. The vehicle may be, for example, an electric vehicle, a hybrid vehicle, or a plug-in hybrid vehicle. The vehicle may be a four-wheeled vehicle or a two-wheeled vehicle but is not limited thereto. FIG. 6 shows a vehicle that includes the battery pack 70 shown in FIG. 5 on the lower body thereof. The vehicle may operate by (e.g., may be powered by) receiving power from the battery pack 70.

The secondary battery pack may include a battery and a battery management system (BMS) for managing the battery. BMS measures through sensors and determines in advance the voltage (V), current (I), and temperature (T) of batteries installed in electric vehicles or ESS, and controls the batteries so that they can perform optimally.

The battery management system may include a detection device, a balancing device, and a control device. The battery module may include a plurality of cells connected to each other in series and/or parallel. The battery modules may be connected to one another in series and/or in parallel.

The detection device may detect a state of a battery (e.g., voltage, current, temperature, etc.) to output state information indicating the state of the battery. The detection device may detect the voltage of each cell constituting the battery or of each battery module. The detection device may detect current flowing through each battery module constituting the battery module or the battery pack. The detection device may also detect the temperature of a cell and/or module on at least one point of the battery and/or an ambient temperature.

The balancing device may perform a balancing operation of a battery module and/or cells constituting the battery module. The control device may receive state information (e.g., voltage, current, temperature, etc.) of the battery module from the detection device. The control device may monitor and calculate the state of the battery module (e.g., voltage, current, temperature, state of charge (SOC), life span (state of health (SOH)), etc.) on the basis of the state information received from the detection device. In addition, on the basis of the monitored state information, the control device may perform a control function (e.g., temperature control, balancing control, charge/discharge control, etc.) and a protection function (e.g., over-discharge, over-charge, over-current protection, short circuit, fire extinguishing function, etc.). In addition, the control device may perform a wired or wireless communication function with an external device of the battery pack (e.g., a higher level controller or vehicle, charger, power conversion system, etc.).

The control device may control charging/discharging operation and protection operation of the battery. To this end, the control device may include charge/discharge control unit, a balancing control unit, and/or a protection unit.

The battery management system is a system that monitors the battery state and performs diagnosis and control, communication, and protection functions, and may calculate the charge/discharge state, calculate battery life or state of health (SOH), cut off, as necessary, battery power (e.g., relay control), control thermal management (e.g., cooling, heating, etc.), perform a high-voltage interlock function, and/or may detect and/or calculate insulation and short circuit conditions.

A relay may be a mechanical contactor that is turned on and off by the magnetic force of a coil or a semiconductor switch, such as a metal oxide semiconductor field effect transistor (MOSFET).

The relay control has a function of cutting off the power supply from the battery if (or when) a problem occurs in the vehicle and the battery system and may include one or more relays and pre-charge relays at the positive terminal and the negative terminal, respectively.

In the pre-charge control, there is a risk of inrush current occurring in the high-voltage capacitor on the input side of the inverter when the battery load is connected. Thus, to prevent inrush current when starting a vehicle, the pre-charge relay may be operated before connecting the main relay and the pre-charge resistor may be connected.

The high-voltage interlock is a circuit that uses a small signal to detect whether or not all high-voltage parts of the entire vehicle system are connected and may have a function of forcibly opening a relay if (or when) an opening occurs at even one location on the entire loop.

There are two types of verification for firmware, which is the internal software of a battery management system (BMS) of products such as an energy storage device (ESS) and a battery pack: white box testing (verification of SW requirements and design details) and black box testing (verification based on customer requirements). The former includes verifying firmware while checking functional information and signals inside software and verifying firmware by intensively verifying functions to check design consistency. The latter includes verifying firmware by focusing on an external interface and function and verifying firmware considering user environments such as combinations of related functions, time operation, and abnormal environment.

Currently, hardware in the loop simulator (HILs) is being utilized as one of the methods for unmanned verification or automated verification of a BMS. HILs may generate a test case sequence to verify the requirements of BMS functions and use the test case sequence to automatically verify BMS firmware.

FIG. 7 is a schematic configuration diagram of a system for automated verification of a BMS based on HILs.

In FIG. 7, automated verification software S/W in a HILs PC 200 creates a test case sequence (program) for testing the firmware operation of a BMS 100 (voltage, current, temperature control, etc.), and modeling software thereof models various items such as a voltage, a current, and a temperature required for the operation of the BMS 100. In addition, the automated verification software S/W in the HILs PC 200 executes the created test case program for firmware of the BMS 100 connected through a controller area network (CAN) communication line 210 to execute a simulation. HILs hardware H/W 300 is connected to the HILs PC 200 through a transmission control protocol/Internet protocol (TCP/IP) connection line 220 and provides modeled data for the items such as the voltage, the current, and the temperature to the BMS 100 through a connection line 310 to control the BMS 100 hardware-wise so that the firmware of the BMS 100 operates in the same situation as an actual situation, thereby intervening in the simulation. As such, the HILs is one of the automated verification methods that combines software to execute a simulation using the test case sequence created for the firmware of the BMS 100 and hardware function control of the BMS 100.

However, while black box testing, which does not require knowledge of the internal structure or design of firmware, can be automated, white box testing, which is for verifying the internal logic of the firmware, is not easy to automate. In particular, in cases where internal variable information of BMS 100 firmware cannot be checked through communication via the communication line 210, when it is intended to verify the corresponding item thereof, there is a difficulty in that the corresponding item should be manually verified by inputting external input conditions and using a separate tool (e.g., a debugging tool within IAR's embedded workbench (EW)).

For example, automated verification of a cell balancing function among functions of the BMS will be briefly described. The cell balancing function of the BMS is a function that lowers the voltage to the minimum cell voltage when a specific cell voltage is high. In this case, the BMS firmware has an algorithm that finds a balancing cell after 20 minutes at a specific voltage or higher in order to enter cell balancing. Therefore, for this, verification is required to check whether an internal variable flag of the firmware has changed after 20 minutes. In this circumstance, since the corresponding flag is not provided externally, it is impossible to check whether the internal variable flag has changed through black box testing, and verification is possible only by checking the corresponding internal variable information in debug mode with integrated development environment (IDE) equipment. However, the process of waiting for 20 minutes for each cell and then checking the internal variable information results in significant loss of time and manpower. Therefore, for efficient, long-term and repetitive verification, there is a great need for automated verification. To this end, a test case sequence that checks whether the internal variable flag changes after 20 minutes for each cell based on HILs may be created to automatically verify changes. However, in this circumstance, monitoring of the internal variables of the BMS firmware should be carried out.

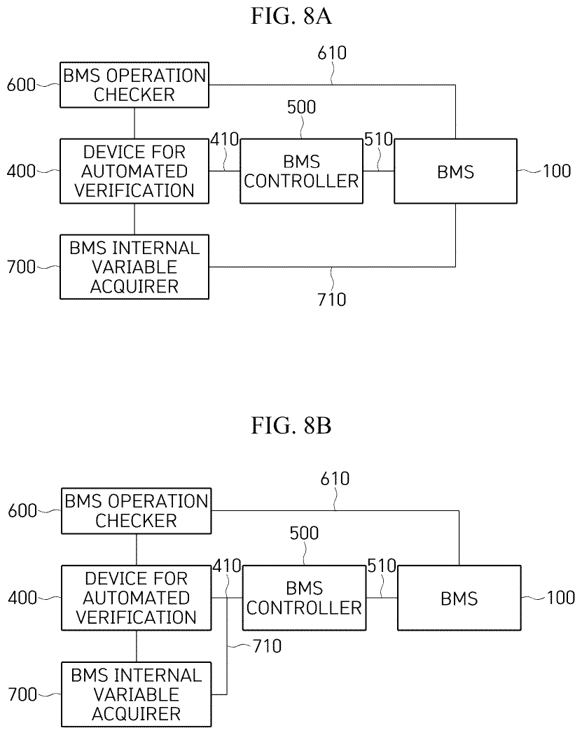

FIG. 8A is a configuration diagram of a system for automated verification according to some embodiments of the present disclosure.

The system for automated verification may include a device for automated verification 400 configured to create a test case sequence (program) for testing firmware operation items (voltage, current, temperature control function, etc.), perform a simulation on the BMS 100 connected through a communication line 610 such as a CAN, and model various items such as the voltage, the current, and the temperature required for the operation of the BMS 100;

a BMS controller 500 that is connected to the device for automated verification 400 (e.g., through a TCP/IP type connection line 410) and controls the BMS 100 to operate in the same manner as in reality by applying modeled data for the operation items such as the voltage, the current, and the temperature to the BMS 100; a BMS operation checker 600 that checks the operation of the BMS 100 connected through the communication line 610 while the device for automated verification 400 executes the created test case sequence and executes a simulation for the BMS 100 and provides information on the checked operation of the BMS 100 to the device for automated verification 400; and a BMS internal variable acquirer 700 that acquires internal variable information of the BMS 100 through a connection line 710 with the BMS 100 during execution of the simulation.

The internal variable acquirer 700 may monitor the internal variables of the BMS 100 firmware and the device for automated verification 400 may check whether the BMS 100 operates normally by linking the internal variable information to the test case sequence for automated verification. Therefore, during verification using white box testing of the internal architecture logic of the firmware of the BMS 100, the internal variable acquirer 700 acquires corresponding internal variable information for items that need to be determined by modifying the internal variable information or verifying the results with the internal variable information and provides the internal variable information to the device for automated verification 400, thereby enabling unmanned automated verification.

The device for automated verification 400 and the BMS controller 500 may be implemented as a HILs system, but are not limited thereto. In addition, the BMS operation checker 600 is an element that may be included in the device for automated verification 400, but is not limited thereto.

FIG. 8B is a configuration diagram of a system for automated verification according to some embodiments.

In the embodiment of FIG. 8A, the connection line 710 through which the BMS internal variable acquirer 700 obtains an internal variable value is connected to the BMS 100, but in the embodiment of FIG. 8B, the connection line 710 may be connected to a connection part between the device for automated verification 400 and the BMS controller 500.

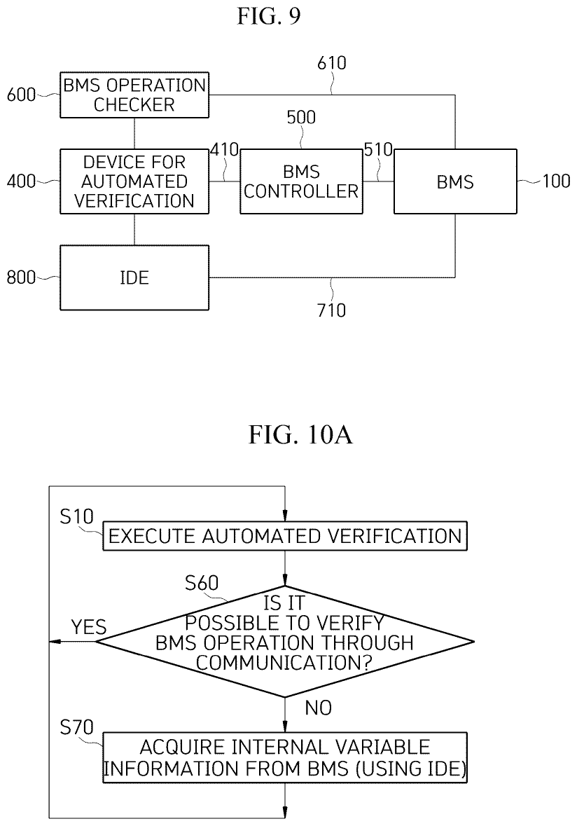

The configuration illustrated in FIG. 9 is an embodiment that shows that the IDE may be used as the BMS internal variable acquirer 700 of FIGS. 8A and 8B. By monitoring the internal variables of the BMS and providing the results to the device for automated verification 400 using the IDE, the device for automated verification 400 may link the provided internal variable information to the test case sequence for automated verification to verify whether the BMS 100 operates in a normal sequence. As a result, automated verification using white box testing of the BMS 100 becomes possible.

The embodiment of FIG. 9 utilizes the fact that some of the IDEs, which are firmware development tools (e.g., IAR's EW), have a function of monitoring the internal variable information of firmware. The internal variable information required for automated verification of the BMS may be exported to the outside using the function of the IDE and linked to the verification logic of the device for automated verification 400 to perform automated verification of the BMS 100.

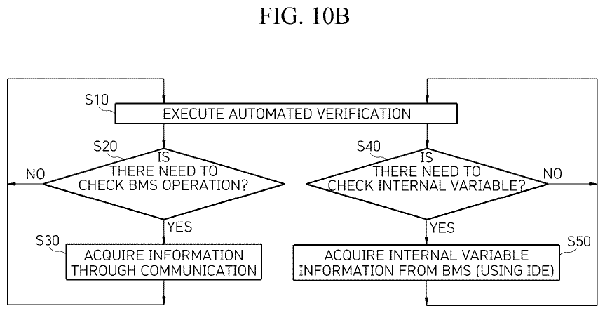

FIG. 10A is a flowchart for describing an embodiment of an operation process in which a BMS internal variable acquirer 700 acquires an internal variable of BMS 100 firmware during execution of automated verification of the device for automated verification 400. Description will be made in connection with FIGS. 8A, 8B, and 8C. The BMS operation checker 600 determines whether the BMS operation may be checked through communication (S60) while the device for automated verification 400 is executing the automated verification of the firmware of the BMS 100 with the created test case sequence of BMS (S10). When it is determined that the BMS operation can be checked, the BMS operation checker 600 checks the operation of the BMS by CAN communication, and the device for automated verification 400 may reflect information on the checked operation of the BMS in the execution of the test case sequence.

Meanwhile, when it is determined that the BMS operation cannot be checked by communication, the BMS internal variable acquirer 700 may obtain internal variable information from the BMS 100 (S70). In this circumstance, as mentioned herein, using the IDE, the firmware of the BMS 100 may be monitored and the required internal variable information may be exported and acquired. The acquired internal variable information may be provided to the device for automated verification 400, and the device for automated verification 400 may execute automated verification (S10) by linking the internal variable information to the test case sequence.

FIG. 10B is a flowchart illustrating a process of an embodiment in which the operation process of FIG. 10A is further detailed.

When the BMS operation checker 600 needs to check the BMS operation (S20) while the device for automated verification 400 is executing the automated verification for the firmware of the BMS 100 using the created test case sequence of the BMS 100 (S10), the BMS operation checker 600 acquire information (a variable value, a flag, etc.) with which the BMS operation may be checked through CAN communication (S30). The acquired operation check information may be provided to the device for automated verification 400 so that the device for automated verification 400 reflects the operation check information in the execution of the test case sequence.

Meanwhile, when the BMS operation checker 600 needs to check a BMS internal variable that cannot be acquired through communication (S40) while the device for automated verification 400 is executing the automated verification for the firmware of the BMS 100 (S10), the BMS internal variable acquirer 700 may obtain the internal variable information from the BMS 100 (S50). In this circumstance, as mentioned herein, using the IDE, the firmware of the BMS 100 may be monitored and the required internal variable information may be exported and acquired. The acquired internal variable information may be provided to the device for automated verification 400, and the device for automated verification 400 may execute automated verification by linking the internal variable information to the test case sequence.

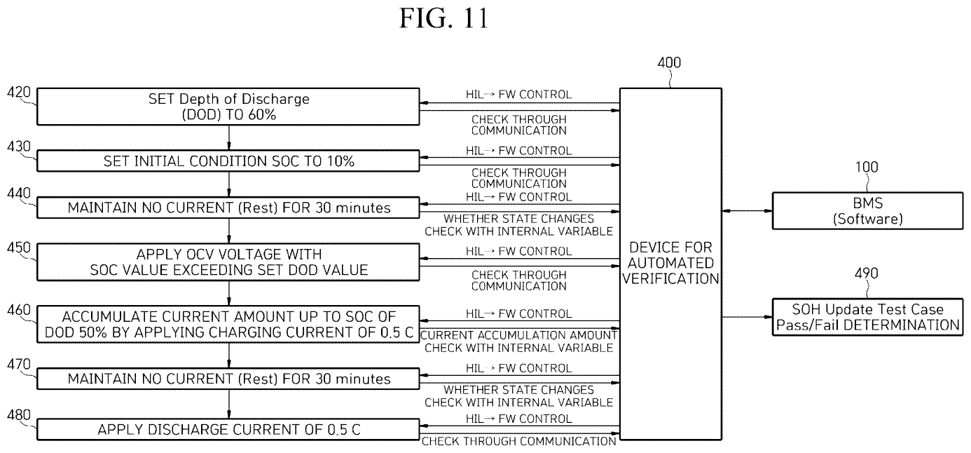

FIG. 11 is a diagram for describing an example of automated verification of BMS firmware using a method for automated verification according to the present disclosure, and illustrates automated verification of a battery state of health (SOH) update function.

Conventionally, in verification based on HILs, a BMS control operation could only be checked through communication. This is because it is not efficient to output all variable information that is not requested by customers externally through communication. In the present disclosure, an internal variable that needs to be checked is brought to the outside using an internal variable acquirer or an IDE interface as mentioned herein, and the internal variable is reflected in the automated verification scenario of HILs, so that the internal variable may be utilized not only for the final determination of verification but also for the verification of intermediate-stage sequence operation.

In FIG. 11, the device for automated verification 400 may be based on the HILs as mentioned herein. The device for automated verification 400 creates a verification program (test case sequence) for automatically verifying the software (or firmware) of the BMS 100, uses the verification program (test case sequence) to execute automated verification of the SOH update function of the firmware of the BMS 100, and outputs a PASS/FAIL determination result 490.

In this example, among control items that the device for automated verification 400 controls (indicated as ‘HIL→FW control’ in FIG. 11) the BMS firmware during execution of automated verification, items of depth of discharge (DOD) set to 60% 420, initial condition state of charge (SOC) set to 10% 430, application of open circuit voltage (OCV) with a SOC value exceeding the set DOD value 450, and application of a discharge current of 0.5 C 480 are operation verification information that may be checked through communication.

Among these control items, items of whether the state changes by maintaining no current (Rest) for 30 minutes 440, current accumulation amount according to current accumulation 460 up to SOC of DOD 50% by applying a charging current of 0.5 C, and whether the state changes by maintaining no current (Rest) for 30 minutes 470 are internal variable information that may be acquired by the internal variable acquirer 700 or the IDE.

Conventionally, there was a difficulty in that the corresponding item should be manually verified by inputting external input conditions and using a debugging tool such as an embedded workbench (EW) of IAR) in integrated development environment (IDE), in cases where internal variable information of firmware cannot be checked through communication, when it is intended to verify the corresponding item thereof, but according to the present disclosure, internal variable information is acquired to be checked externally during operation of BMS firmware of an ESS, a battery pack, etc. and this internal variable information is linked to a test case sequence for automated verification to automatically determine the internal variable values under specific conditions, thereby enabling more complete unmanned automatic verification, especially in long-term or repetitive BMS firmware tests. Although the present disclosure has been described herein with respect to embodiments thereof, the present disclosure is not limited thereto. Various modifications and variations can be made thereto by those skilled in the art within the spirit of the present disclosure as defined by the appended claims and their equivalents.

What is claimed is:

1. A system for automated verification of a battery management system (BMS), comprising:
a device for automated verification configured to create a test case sequence for testing firmware operation items of the BMS, perform a simulation on the BMS, and model operation items of the BMS;
a BMS controller that is connected to the device for automated verification and controls the BMS to operate by applying modeled data for the operation items to the BMS; and
a BMS internal variable acquirer that acquires internal variable information of the BMS during performance of the simulation.

2. The system as claimed in claim 1, wherein the BMS internal variable acquirer is configured to provide the internal variable information to the device for automated verification, and
the device for automated verification is configured to simulate operation of the BMS by linking the internal variable information to the test case sequence.

3. The system as claimed in claim 1, wherein the device for automated verification and the BMS controller are configured as a hardware in a loop simulator (HILs) system.

4. The system as claimed in claim 1, further comprising a BMS operation checker that checks operation of the BMS while the device for automated verification executes the created test case sequence to execute the simulation for the BMS and provides information on the checked operation of the BMS to the device for automated verification.

5. The system as claimed in claim 1, wherein the BMS internal variable acquirer is configured to monitor an internal variable of the BMS using an integrated development environment (IDE) and provide monitoring results to the device for automated verification.

6. The system as claimed in claim 5, wherein the BMS internal variable acquirer is configured to monitor firmware of the BMS and export required internal variable information to be acquired using the IDE when operation of the BMS cannot be checked through communication while the device for automated verification is executing automated verification for the BMS.

7. The system as claimed in claim 1, wherein the BMS internal variable acquirer is configured to acquire internal variable information from the BMS when operation of the BMS cannot be checked through communication while the device for automated verification is executing automated verification for the BMS.

8. A device for automated verification of a battery management system (BMS), the device being configured to:
create a test case sequence for testing a firmware operation item of the BMS;
model an operation item of the BMS;
perform a simulation on the BMS;
transmit modeled data for the operation item to a BMS controller to control operation of the BMS; and
receive internal variable information of the BMS during performance of the simulation and reflect internal variable information in the test case sequence.

9. The device as claimed in claim 8, wherein the device for automated verification is configured as hardware in a loop simulator (HILs) system.

10. The device as claimed in claim 8, wherein the BMS internal variable information is a result obtained by monitoring an internal variable of the BMS by an integrated development environment (IDE).

11. A method for automated verification of a battery management system (BMS), comprising:
performing a simulation on the BMS using a test case sequence created to test a firmware operation item of the BMS and data obtained by modeling an operation item of the BMS; and
acquiring internal variable information of the BMS during execution of the simulation.

12. The method as claimed in claim 11, further comprising simulating operation of the BMS by linking the acquired internal variable information to the test case sequence.

13. The method as claimed in claim 11, wherein the performing of the simulation is executed by hardware in a loop simulator (HILs) system.

14. The method as claimed in claim 11, further comprising checking operation of the BMS and linking information on the checked operation to the test case sequence while executing the simulation for the BMS.

15. The method as claimed in claim 11, wherein the internal variable information of the BMS is a result obtained by monitoring an internal variable of the BMS using an integrated development environment (IDE).

16. The method as claimed in claim 15, wherein the internal variable information of the BMS is acquired by monitoring firmware of the BMS and exporting required internal variable information using the IDE when operation of the BMS cannot be checked through communication during the simulation for the BMS.

17. The method as claimed in claim 11, wherein the internal variable information of the BMS is acquired from the BMS when operation of the BMS cannot be checked through communication while the simulation for the BMS is being executed.
